(19) United States
(12) Patent Application Publication
(10) Pub. No.: US 2009/0035703 A1
(43) Pub. Date: Feb. 5, 2009

(54) Regeneratable, structured plate comprising oxidation catalysts

(75) Inventors: Martin Mennig, Quierschied (DE); Peter Oliveira, Saabruecken (DE); Helmut Schmidt, Saarbruecken-Guedingen (DE)

Correspondence Address: GREENBLUM & BERNSTEIN, P.L.C., 1950 ROLAND CLARKE PLACE, RESTON, VA, 20191, US

(73) Assignee: LEIBNIZ-INSTITUT FUER NEUE MATERIALIEN GEMEINNUETZIGE GMBH, Saarbruecken (DE)

(21) Appl. No.: 11/920,829

(22) PCT Filed: May 24, 2006
(86) PCT No.: PCT/EP2006/004979

§ 371 Date: Mar. 4, 2008

(30) Foreign Application Priority Data
May 24, 2005 (DE) 10 2005 023 871.8

(51) Int. Cl. G03F 7/20; B05D 5/00; B32B 3/10; B41N 1/00

(52) U.S. Cl. 430/302; 427/2.24; 428/195.1; 101/453

(57) ABSTRACT

A regeneratable plate having a structured surface comprising hydrophilic and hydrophobic regions. The plate comprises a substrate, a first layer comprising a hydrophilic oxidation catalyst arranged on the substrate, and a second layer which is hydrophobic and is imagewise arranged on the first layer to thereby afford the structured surface comprising hydrophobic regions and hydrophilic regions. A process for making the plate by imagewise exposure is also described.

The present invention relates to processes for the production of regeneratable plates having a structured surface comprising hydrophilic and hydrophobic regions, the layer which forms the hydrophilic regions containing an oxidation catalyst, to the regeneratable plates obtainable therefrom and having a structured surface, to a process for regenerating these plates, to planographic printing processes and to further uses for these regeneratable, structured plates.

The structuring of surfaces is an interesting technique and there are various processes for achieving this. Thus, for example in photolithography, soluble regions which are produced, for example, by exposure to masks, laser inscribing or two-wave mixing can be dissolved out of photosensitive materials, and surface structures can thus be achieved. In offset printing, the polarity of the surfaces is changed by means of a photolithographic process and wettable and nonwettable regions (hydrophilic/hydrophobic regions) are thus produced. In addition, by means of chemical surface modification, reactive groups can be bound to surfaces, which can be selectively structured, for example, by means of laser ablation. Functional surface structures can thus be produced. However, common to all these processes is that they cannot be cancelled out, i.e. are not reversible.

The establishing of hydrophilicity or hydrophobicity of surfaces is also technically important since, in addition to the use in printing processes, further applications are known in which it is necessary to make a surface either hydrophilic or hydrophobic as required without major interventions being required for this purpose. Layers of an oxidic material frequently exhibit hydrophilic properties. On the other hand, surfaces which are hydrophobicized with silicone layers have pronounced hydrophobic behavior and form contact angles of more than 100° with water. Metal, glass or ceramic surfaces likewise become hydrophobic if they are covered with thin oil films.

As stated, surface-structured systems comprising hydrophilic and hydrophobic regions can be used, for example, for printing processes in which a material is transferred imagewise to a receiving medium. As a result for example, images can be printed, information can be recorded or structures, for example for circuit boards, can be built up. The production of these surface-structured systems is complicated and expensive. As a rule, a multistage process which comprises complex chemical reaction chains and/or etching stages is required. This also means long production times and a high chemical demand with the associated disposal problems. Particularly in the case of micro- and nanostructures, these difficulties increase owing to the required accuracy. In addition, once produced, the surface structures are frequently no longer changeable, so that the entire substrate has to be discarded in the event of damage or if it desired to change the image to be printed.

The object according to the invention was to provide a process by means of which a surface structure comprising hydrophobic and hydrophilic regions, which is suitable for printing on materials, can be produced in a simple, economical and rapid manner, and by means of which structures in the micron range can also be accurately represented. In particular, the plates used should be regeneratable, i.e. the process should permit a variable and reversible design of defined surface structures so that the plates can be repeatedly restructured so that reuse of the plates is possible.

The object according to the invention was surprisingly achieved by rendering hydrophobic a coating system which is effective as an oxidation catalyst and comprises a hydrophilic oxidation catalyst on a surface comprising organic substances or substances which contain organic hydrophobic groups, so that the surface can no longer be wetted with water, aqueous solutions or suspensions, and then selectively exposing the system obtained so that the hydrophobic layer is locally heated in the irradiated area and is completely oxidized by the oxidation catalyst and thus removed. The area irradiated in this manner is wettable again because the hydrophilic oxidation catalyst present underneath has a wettable surface.

Accordingly, according to the invention, a process for the production of a regeneratable plate having a structured surface comprising hydrophilic and hydrophobic regions is provided, in which the surface of a regeneratable plate, which comprises a substrate and a layer present thereon and comprising a material which contains an inorganic oxidation catalyst, is coated with a hydrophobic layer and exposed imagewise, catalyst and layer being heated in the exposed regions by the exposure so that the hydrophobic layer is oxidatively decomposed in the exposed regions with baring of the hydrophilic oxidation catalyst present underneath.

By means of the oxidation catalyst, it is surprisingly possible to heat a hydrophobic layer stable at room temperature by imagewise exposure in the exposed regions to temperatures just sufficiently high for decomposing them oxidatively, while the unexposed regions remain sufficiently cool in order not to decompose. Surprisingly, the heat selectivity is so high that even structures in the nanometer range can be produced thereby.

The process according to the invention is distinguished in particular by the regeneratability, i.e. the plates having a structured surface can surprisingly be regenerated since a plate comprising the substrate and the layer comprising material which contains a hydrophilic oxidation catalyst, which has been structured with a hydrophobic layer, can be cleanly freed from the hydrophobic regions present thereon. This can be effected by uniform exposure in which the hydrophobic regions are destroyed by thermocatalytic oxidation. Here, thermocatalytic means that the oxidative decomposition takes place catalytically at elevated temperature. As a result of this oxidative decomposition, in contrast to a simple thermal decomposition which leads to pyrolysis residues, virtually no remainders or residues of the hydrophobic constituents remain on the plate. Consequently, the plate can be reused without any limitations for further structuring by imparting of water repellency and imagewise exposure.

Since the plate or the cylinder having the layer containing the hydrophilic oxidation catalyst does of course have a disproportionally greater material value than the hydrophobic layer, the reusability or regeneratability of the plate is of particular importance from the economic point of view.

As a result of the imagewise exposure, a corresponding image or pattern is formed from the hydrophobic and hydrophilic regions on the surface. For the subsequent printing, the resulting two-dimensional pattern on the surface is particularly relevant.

The resulting pattern may be any desired pattern. Regular or irregular patterns are possible. Regular forms are, for example, dots, lines or areas, such as triangles, rectangles, polygons, circles or ellipses. Curved lines or irregular areas are of course also possible. By a combination of individual forms, the desired overall pattern can be formed, for example for reproduction of numbers, letters, images, circuits or other information or for building up certain structures. The pattern to be printed may correspond to the hydrophilic region or the hydrophobic region.

The hydrophilic layer and the hydrophobic layer are present on the substrate. The substrate may have any suitable form. It is present, for example, as a flat or cylindrical substrate which is suitable, for example, as a printing plate or printing roller. In the description and the claims, the plate accordingly also includes a cylinder or a roller. Flat substrates can, for example, be clamped on a cylinder. The plate according to the invention can accordingly likewise assume any suitable expedient form, for example flat or cylindrical. The substrate may be any material suitable for the purpose. Examples of suitable materials are metals or metal alloys, glass, ceramic, including oxide ceramic and glass ceramic, paper or plastic, including rubber. This substrate may also be in the form of a sheet.

Of course, substrates which are provided with a surface layer, for which the abovementioned materials can likewise be used, are also possible. The surface layer may be, for example, a metallization, an enameling, for example an enameled metal sheet, ceramic layer or a coating. Ceramic surfaces may be, for example, thin coverings of ceramic components on metals. The substrates may be pretreated. For example, they may be cleaned, for example with commercially available alkaline cleaners, or prepared for coating, for example by corona treatment.

Examples of metals or metal alloys are steel, including stainless steel, chromium, copper, titanium, tin, zinc, brass and aluminum. Examples of glass are soda-lime glass, borosilicate glass, lead crystal and silica glass. For example, flat glass, hollow glass, such as container glass, or laboratory apparatus glass is possible. The ceramic is, for example, a ceramic based on the oxides SiO₂, Al₂O₃, ZrO₂ or MgO or the corresponding mixed oxides. A coated surface may be formed from customary primer coats or varnishes based on organic binders. If appropriate, the substrate itself may be the hydrophilic layer and so the hydrophobic layer is applied directly to a substrate having hydrophilic surface properties. However the hydrophilic layer is preferably present on a separate substrate.

A layer comprising the hydrophilic oxidation catalyst is present on the substrate, and a hydrophobic layer is applied to said oxidation catalyst. The concept of hydrophilicity/hydrophobicity is very well known to the person skilled in the art as a basic concept of chemistry. Hydrophobic substances repel water whereas hydrophilic substances attract water. The hydrophilic character can be formed, for example, by hydroxyl, oxy, carboxylate, sulfate or sulfonate functions or polyether chains in the substance. A hydrophobic character is typically produced, for example, by hydrocarbon radicals, such as alkyl radicals or aromatic radicals in the substance.

The hydrophobic or hydrophilic character of the layers is determined in particular by the substances used for the layers and, if appropriate, the modification thereof. Which materials and processing methods the person skilled in the art should choose is readily evident to him. The hydrophobic/hydrophilic character of a layer can be determined, for example, by the contact angle with water or an another suitable solvent.

The difference between the hydrophilic character of one layer and the hydrophobic character of the other layer need be only so great that sufficient selectivity of the material to be printed for one of the two layers is ensured. The required adjustments are known to the person skilled in the art. Preferably, the hydrophilic region has a contact angle of ≦300 with water, measured on a smooth surface, while the hydrophobic region has a contact angle of ≧85° with water, measured on a smooth surface.

The lower layer consists of a material which contains a hydrophilic oxidation catalyst, with the result that a hydrophilic layer is obtained at least in the areas where the oxidation catalyst is present. The oxidation catalyst comprises a catalytically active species and, if appropriate, a support material. In addition to the oxidation catalyst, the material may contain a binder in order to ensure or to improve the adhesion of the oxidation catalyst to the substrate.

The lower layer contains one or more hydrophilic oxidation catalysts, these preferably being oxide catalysts. Oxidation catalysts have long been known and the person skilled in the art can easily choose conventional oxidation catalysts. A review article is to be found, for example, in Ullmanns Encyklopädie der technischen Chemie [Ullmann's Encyclopedia of Industrial Chemistry], 4th edition, Vol. 13, pages 517-570; examples of oxidation catalysts are shown in Table 15F on page 548, and the oxide catalysts discussed below are addressed in general on pages 530 and 531. The oxidation catalyst is in particular an inorganic oxidation catalyst.

The oxidation catalysts are capable of catalyzing oxidation reactions on thermal activation. Depending on the conditions and materials chosen, the oxidation of organic substances can progress during the catalysis until the organic substances decompose with the formation of volatile or vaporizable fragments (e.g. low molecular weight carboxylic acids, CO₂).

The suitable temperature range does of course depend on the materials present (e.g. the hydrophobic layer), catalysts and states; as a rule, the components are chosen so that the catalytic decomposition reaction does not take place at ambient temperature but only on heating, for example at a temperature of 40° C. or 60° C. or more for the decomposition reaction. Preferably, the temperature for the thermal activation of the decomposition reaction is in the range from 100° C. to 900° C., preferably 100° C. to 700° C. and particularly preferably 200° C. to 500° C. Depending on the hydrophilic and hydrophobic layers, the oxidation catalyst can be chosen in a suitable manner with regard to the desired temperature range. The selectivity of the oxidative decomposition reaction is achieved by the temperature difference between exposed and unexposed regions.

The thermocatalytically active oxidation catalysts comprise catalytically active species. The catalytically active species are preferably oxides, in particular metal oxides and especially transition metal oxides. Transition metals are understood as meaning, as usual, the elements of subgroups I to VIII of the Periodic Table of the Elements and the lanthanide and actinide elements. The oxidation catalyst preferably comprises an oxide of at least one transition metal selected from La, Ce, Ti, Zr, V, Cr, Mo, W, Mn, Fe, Co, Ni, Cu, Nb, Ta, Ag and Zn.

Multicomponent systems which consist of an oxide of two or more transition metals are preferably used as oxidation catalysts. The structure obtained may be complex and may comprise metal oxide mixtures of different metal oxides or mixed metal oxides (an oxide with at least two different metals) or mixtures thereof and metals of different oxidation states. Sometimes, the structures are not even completely clear in all details.

In addition to the abovementioned transition metals, the oxidation catalyst may contain additional elements, such as Bi, Sn, P, Sb, alkali metals or alkaline earth metals, as promoters for increasing the activity. These promoters or cocatalysts may be used, for example, in amounts of 1 to 5% by weight, based on the transition metal oxide used. Suitable cocatalysts are, for example, K, Mg, Ca, Ba and Sr salts and Al, Si and Sn oxides. Suitable salts are, for example, the corresponding halides, hydroxides, nitrates, carbonates, phosphates or carbonates. Depending on the conditions used, the anions of the salts used may remain in the catalyst, may be washed out or may be converted. Thus, for example, nitrates may be evaporated off during a calcination as oxides of nitrogen, possibly leaving behind oxides.

In a preferred embodiment, the oxidation catalysts contain oxide catalysts of at least two transition metals and, if appropriate, promoters. A preferred oxide catalyst contains, for example, Mn and Ce, if appropriate with further transition metals, such as oxides of Mn/Co/Ce, Mn/Cu/Ce, Mn/Ni/Ce, Mn/Fe/Ce or Mn/Co/Ni/Ce. A further preferred oxide catalyst comprises an oxide Cu/V/La. Oxide catalysts which contain manganese and copper, e.g. Mn/Cu/Ce, are particularly preferred, Mn/Cu/K oxides with potassium as promoter being even more preferred. The other oxide catalysts may of course also contain promoters.

In the transition metal oxides, for example, the following amounts of the corresponding metal oxides may be preferred in the metal oxide mixture: Ce: 1-70% by weight, V: 5-70% by weight, Mn: 20-95% by weight, Fe: 20-95% by weight, Co: 1-50% by weight, Ni: 1-50% by weight and/or Cu: 1-95% by weight. Examples of individual transition metal oxides are CuO, Cu₂O, V₂O₅, MnO₂ (pyrolusite), γ-MnO₂, CO₃O₄, CO₂O₃, CoO and CeO₂.

In a preferred embodiment, the oxidation catalysts also comprise a support material. The support materials are as a rule catalytically inert and serve, for example, for the formation of a large surface area. Such support materials are known to the person skilled in the art in the area of catalysts and the conventional support materials can be used. Examples of support materials are aluminas, silicas, in particular silica gels, active carbon, silicon carbide, titanium dioxide, magnesium oxide, various silicates and zeolites. Oxidic support materials are particularly preferably used. The porosity and the specific surface area of the support can be adjusted as required by methods known to the person skilled in the art.

The oxidation catalysts can be prepared by the conventional processes known to the person skilled in the art, as explained in general in the abovementioned article from Ullmanns Encyklopädie der technischen Chemie [Ullmann's Encyclopedia of Industrial Chemistry]. The oxidation catalysts may be, for example, in the form of precipitated catalysts or in the form of impregnated catalysts and are then subjected to further treatment steps, such as drying or calcination. In the present invention, preferably used catalysts are those which are obtained by impregnation of catalytically active species or precursors thereof on support materials and if appropriate, further treatment stages.

The oxidation catalysts are hydrophilic and as a rule may be present, for example, in the form of particles in the layer. The particle diameter of the oxidation catalyst particles can be chosen according to requirements. In a preferred embodiment, the oxidation catalyst is an IR-absorbing substance in order to enhance the heating effect by exposure in the IR wavelength range.

Preferably, 1% by weight to 100% by weight, more preferably 5% by weight to 70% by weight and in particular 10% by weight to 25% by weight of the finished layer of hydrophilic oxidation catalyst are preferred.

The lower layer may consist only of the oxidation catalyst, so that the coating composition for application of this layer to the substrate consists only of the oxidation catalyst and, if appropriate, solvent. The coating composition for the production of the lower layer preferably also contains, in addition to the hydrophilic oxidation catalyst, a binder for improving the adhesion of the layer to the substrate and/or the strength of the layer. Binders which may be used are organic polymers but they are usually inorganic and in particular organically modified inorganic polycondensates or precursors thereof and/or nanoscale particles. The composition of the advantageous polycondensates and nanoscale particles is described below. The binder is preferably present in the form of a sol.

The inorganic or organically modified inorganic polycondensate is in particular a condensate of semimetals or metals M, which are also referred to as glass- or ceramic-forming elements, in particular from main groups III to V and/or subgroups II to V of the Periodic Table of the Elements and Mg. They are preferably the elements Si, Al, B, Sn, Ti, Zr, Mg, V or Zn, in particular those of Si, Al, Ti, Zr and Mg or mixtures of two or more of these elements. Other semi-metals or metals M can of course also be incorporated, in particular those of main groups I and II of the Periodic Table of the Elements (e.g. Na, K and Ca) and of subgroups VI to VIII of the Periodic Table of the Elements (e.g. Mn, Cr, Fe and Ni). It is also possible to use lanthanoids. In the case of the organically modified inorganic polycondensates, organic side groups are present in the condensate.

The binder is preferably obtained from hydrolyzable compounds by the sol-gel process. In the sol-gel process, hydrolyzable compounds are usually hydrolyzed with water, if appropriate with acidic or basic catalysis, and, if appropriate, at least partly condensed. The hydrolysis and/or condensation reactions lead to the formation of compounds or condensates having hydroxyl groups, oxo groups and/or oxo bridges, which serve as precursors. Stoichiometric amounts of water may be used, but also smaller or larger amounts. The resulting sol can be adjusted to the viscosity desired for the coating composition by means of suitable parameters, e.g. degree of condensation, solvent or pH. Further details of the sol-gel process are described, for example, in C. J. Brinker, G. W. Scherer: “Sol-Gel Science—The Physics and Chemistry of Sol-Gel-Processing”, Academic Press, Boston, San Diego, New York, Sydney (1990).

Preferably used binders are organically modified inorganic polycondensates obtained by the sol-gel process or precursors thereof. The organically modified inorganic polycondensates or precursors thereof preferably comprise polyorganosiloxanes or precursors thereof. The organic radicals can, if appropriate, contain functional groups via which crosslinking is possible. Coating compositions based on organically modified inorganic polycondensates are described, for example, in DE 19613645, WO 92/21729 and WO 98/51747, which are hereby incorporated by reference in their entirety.

The organically modified inorganic polycondensates are formed from hydrolyzable compounds which, in addition to hydrolyzable groups, also have at least one nonhydrolyzable group. It is possible to use exclusively hydrolyzable compounds having at least one nonhydrolyzable group for the preparation of the condensates, but they are usually used as a mixture with hydrolyzable compounds without nonhydrolyzable groups.

Compounds having hydrolyzable groups may therefore be used as hydrolyzable starting compounds for the preparation of the organically modified inorganic polycondensates, at least a part, e.g. at least 10 mol %, of these compounds also comprising nonhydrolyzable groups. Preferably at least 50 mol % and more preferably at least 60 mol % of the hydrolyzable starting compounds used contain at least one nonhydrolyzable group. The ratio of hydrolyzable compounds without nonhydrolyzable groups to hydrolyzable compounds with at least one nonhydrolyzable group is, for example, 5-50:50-95 and preferably 1:1 to 1:6 and more preferably 1:3 to 1:5, e.g. 1:4. It is also possible to use partly reacted oligomers, but the stated amounts always relate to monomeric starting compounds.

Hydrolyzable organosilanes or oligomers thereof are preferably used as hydrolyzable starting compounds which have at least one nonhydrolyzable group. A preferred binder is accordingly preferably based on a polycondensate, for example obtainable by the sol-gel process, or precursors thereof based on one or more silanes of the general formula

RₐSiX₍₄₋ₐ₎ (I)

in which the radicals R are identical or different and are nonhydrolyzable groups, the radicals X are identical or different and are hydrolyzable groups or hydroxyl groups and a has the value 1, 2 or 3, or an oligomer derived therefrom. The value a is preferably 1 or 2.

In the general formula (I), the hydrolyzable groups X, which may be identical or different from one another, are, for example, hydrogen or halogen (F, Cl, Br or I), alkoxy (preferably C₁₋₆-alkoxy, such as, for example, methoxy, ethoxy, n-propoxy, isopropoxy and butoxy), aryloxy (preferably C₆₋₁₀-aryloxy, such as, for example, phenoxy), acyloxy (preferably C₁₋₆-acyloxy, such as, for example, acetoxy or propionyloxy), alkylcarbonyl (preferably C₂₋₇-alkylcarbonyl, such as, for example, acetyl), amino, monoalkylamino or dialkylamino having preferably 1 to 12, in particular 1 to 6, carbon atoms. Preferred hydrolyzable radicals are halogen, alkoxy groups and acyloxy groups. Particularly preferred hydrolyzable radicals are C₁₋₄-alkoxy groups, in particular methoxy and ethoxy.

The nonhydrolyzable radicals R, which may be identical or different from one another, may be nonhydrolyzable radicals R having a functional group via which, if appropriate, crosslinking is possible, or preferably may be nonhydrolyzable radicals R without such a functional group.

The nonhydrolyzable radical R without a functional group is, for example, alkyl (preferably C₁₋₈-alkyl, such as methyl, ethyl, n-propyl, isopropyl, n-butyl, sec-butyl and tert-butyl, pentyl, hexyl, octyl or cyclohexyl) alkenyl (preferably C₂₋₆-alkenyl, such as, for example, vinyl, 1-propenyl, 2-propenyl and butenyl), alkynyl (preferably C₂₋₆-alkynyl, such as, for example, acetylenyl and propargyl), aryl (preferably C₆₋₁₀-aryl, such as, for example phenyl and naphthyl) and alkylaryls and arylalkyls derived therefrom. The radicals R and X can, if appropriate, have one or more customary substituents, such as, for example, halogen or alkoxy.

Preferred examples are alkyltrialkoxysilanes, such as methyltri(m)ethoxysilane, dialkyldialkoxysilanes, aryltrialkoxysilanes, such as phenyltri(m)ethoxysilane, and diaryldialkoxysilanes, such as diphenyldi(m)ethoxysilane, alkyl being in particular C₁₋₈-alkyl and alkoxy being in particular methoxy or ethoxy. Preferred compounds are methyltriethoxysilane (MTEOS), ethyltriethoxysilane, phenyltriethoxysilane (PTEOS) or dimethyldiethoxysilane.

The nonhydrolyzable radical R having a functional group via which, if appropriate, crosslinking is possible may comprise, as a functional group, for example, an epoxide (e.g. glycidyl or glycidyloxy), hydroxyl, ether, amino, monoalkylamino, dialkylamino, optionally substituted anilino, amido, carboxyl, acryloyl, acryloyloxy, methacryl, methacryloyloxy, mercapto, cyano, alkoxy, isocyanato, aldehyde, alkylcarbonyl, acid anhydride and phosphoric acid group, epoxide and amino groups being preferred. These functional groups are bonded to the silicon atom via alkylene, alkenylene or arylene bridging groups which may be interrupted by oxygen or —NH-groups. The bridging groups preferably contain 1 to 18, preferably 1 to 8 and in particular 1 to 6 carbon atoms.

Said divalent bridging groups and any substituents present, such as in the case of the alkylamino groups, are derived, for example, from the abovementioned monovalent alkyl, alkenyl or aryl radicals. Of course, the radical R may also have more than one functional group.

Examples of silanes having functional groups are γ-glycidyloxypropyltrimethoxysilane (GPTS), γ-glycidyloxypropyltriethoxysilane (GPTES),3-isocyanatopropyltriethoxysilane, 3-isocyanatopropyldimethylchlorosilane, 3-aminopropyltrimethoxysilane (APTS),3-aminopropyltriethoxysilane, 3-(amino-ethylamino)propyltriethoxysilane, N—[N′-(2′-aminoethyl)-2-aminoethyl]-3-amino-propyltrimethoxysilane, hydroxymethyltriethoxysilane, bis(hydroxyethyl)-3-aminopropyltriethoxysilane, N-hydroxyethyl-N-methylaminopropyltriethoxysilane, 3-(meth)acryloyloxypropyltriethoxysilane and 3-(meth)acryloyloxypropyltrimethoxysilane. Further examples of hydrolyzable silanes which can be used according to the invention are also to be found, for example, in EP-A-195493.

Suitable additional compounds without nonhydrolyzable groups are in particular hydrolyzable silanes of the formula

SiX₄ (II)

in which X is defined as in formula (I). Examples of hydrolyzable silanes which can be used for the preparation of the binder are Si(OCH₃)₄, Si(OC₂H₅)₄, Si(O-n- or -i-C₃H₇)₄, Si(OC₄H₉)₄, SiCl₄, HSiCl₃, Si(OOCCH₃)₄. Among these silanes, tetraalkoxysilanes and in particular tetramethoxysilane and tetraethoxysilane (TEOS) are preferred.

The organically modified inorganic polycondensate is preferably formed from a tetraalkoxysilane and at least one silane selected from alkyltrialkoxysilanes, dialkyldialkoxysilanes, aryltrialkoxysilanes and diaryldialkoxysilanes, mixtures of methyltriethoxysilane (MTEOS) and TEOS being particularly preferred. The organically modified inorganic polycondensate can also be formed, for example, from pure MTEOS.

Further hydrolyzable compounds without nonhydrolyzable groups, which can be used in addition to or instead of the silicon compounds of the formula (II), have in particular the general formula MX_{b}, in which M is the above-defined glass- or ceramic-forming element M, except for Si, X is a hydrolyzable group or a hydroxyl, it being possible for two groups X to be replaced by an oxo group, and b corresponds to the valency of the element and is in general 3 or 4. Examples of the hydrolyzable groups X, which may be identical or different from one another, are hydrogen, halogen (F, Cl, Br or I, in particular Cl or Br), alkoxy (e.g. C₁₋₆-alkoxy, such as, for example, methoxy, ethoxy, n-propoxy, isopropoxy and n-butoxy, isobutoxy, sec-butoxy or tert-butoxy), aryloxy (preferably C₆₋₁₀-aryloxy, such as, for example phenoxy), alkaryloxy, e.g. benzoyloxy, acyloxy (e.g. C₁₋₆-acyloxy, preferably C₁₋₄-acyloxy, such as, for example acetoxy or propionyloxy), amino and alkylcarbonyl (e.g. C₂₋₇-alkylcarbonyl, such as acetyl). Two or three groups X may also be linked to one another, for example in the case of Si-polyol complexes with glycol, glycerol or pyrocatechol. Said groups can, if appropriate, contain substituents, such as halogen or alkoxy. Preferred hydrolyzable radicals X are halogen, alkoxy groups and acyloxy groups.

The titanium compounds which may be used are in particular hydrolyzable compounds of the formula TiX₄. Specific and preferably used titanates for the preparation of a coating composition by the sol-gel process are TiCl₄, Ti(OCH₃)₄, Ti(OC₂H₅)₄, Ti(2-ethylhexyloxy)₄, Ti(n-OC₃H₇)₄ or Ti(i-OC₃H₇)₄. Further examples of usable hydrolyzable compounds of elements M are Al(OCH₃)₃, Al(OC₂H₅)₃, Al(O-n-C₃H₇)₃, Al(O-i-C₃H₇)₃, Al(O-n-C₄H₉)₃, Al(O-sec-C₄H₉)₃, AlCl₃, AlCl(OH)₂, Al(OC₂H₄OC₄H₉)₃, ZrCl₄, Zr(OC₂H₅)₄, Zr(O-n-C₃H₇)₄, Zr(O-i-C₃H₇)₄, Zr(OC₄H₉)₄, ZrOCl₂, Zr(2-ethylhexyloxy)₄, and Zr compounds which have complexing radicals, such as, for example, β-diketone and (meth)acryloyl radicals, sodium methylate, potassium acetate, boric acid, BCl₃, B(OCH₃)₃, B(OC₂H₅)₃, SnCl₄, Sn(OCH₃)₄, Sn(OC₂H₅)₄, VOCl₃ and VO(OCH₃)₃.

Purely inorganic polycondensates or precursors as binder may be formed in an analogous manner from one or more hydrolyzable compounds of the formula (II) or of the formula MX_{b}, as defined above.

Nanoscale particles, alone or in addition to said polycondensates (also referred to condensates), may also be used as binders. The nanoscale particles may have the same composition as the polycondensates described above. In the sol-gel process, for example, the product may sometimes be obtained as a polycondensate or in the form of nanoscale particles, depending on the conditions chosen. Further examples of nanoscale particles are described below.

The nanoscale solid particles, also referred to as nanoparticles below, may be organic nanoparticles, for example comprising a plastic, or preferably inorganic nanoparticles. The nanoparticles preferably consist of metal, including metal alloys, metal compounds, in particular metal chalcogenides, particularly preferably the oxides and sulfides, metals here also including B, Si and Ge. It is possible to use one type of nanoparticles or a mixture of nanoparticles. The binder may advantageously be a combination of nanoscale particles and organically modified inorganic polycondensates.

Further nanoparticles may comprise any desired metal compounds. Examples are (optionally hydrated) oxides, such as ZnO, CdO, SiO₂, GeO₂, TiO₂, ZrO₂, CeO₂, SnO₂, Al₂O₃ (in particular boehmite, AlO(OH), also as aluminum hydroxide), B₂O₃, In₂O₃, La₂O₃, Fe₂O₃, Fe₃O₄, Cu₂O, Ta₂O₅, Nb₂O₅, V₂O₅, MoO₃ or WO₃; further chalcogenides, such as, for example, sulfides (e.g. CdS, ZnS, PbS and Ag₂S), selenides (e.g. GaSe, CdSe and ZnSe) and tellurides (e.g. ZnTe or CdTe); halides, such as AgCl, AgBr, Agl, CuCl, CuBr, Cdl₂ and Pbl₂; carbides, such as CdC₂ or SiC; arsenides, such as AlAs, GaAs and GeAs; antimonides, such as InSb; nitrides, such as BN, AlN, Si₃N₄ and Ti₃N₄; phosphides, such as GaP, InP, Zn₃P₂ and Cd₃P₂; phosphates, silicates, zirconates, aluminates, stannates and the corresponding mixed oxides (luminescence pigments comprising Y- or Eu-containing compounds, spinels, ferrites or mixed oxides having a perovskite structure, such as BaTiO₃ and PbTiO₃).

The nanoscale inorganic solid particles are preferably an oxide or hydrated oxide of Si, Ge, Al, B, Zn, Cd, Ti, Zr, Ce, Sn, In, La, Fe, Cu, Ta, Nb, V, Mo or W, particularly preferably of Si, Al, B, Ti and Zr. Oxides or hydrated oxides are particularly preferably used. Preferred nanoscale inorganic solid particles are SiO₂, Al₂O₃, ITO, ATO, AlOOH, Ta₂O₅, ZrO₂ and TiO₂, SiO₂ being particularly preferred.

The preparation of these nanoscale particles can be effected in a customary manner, for example by flame pyrolysis, plasma methods, colloid techniques, sol-gel processes, controlled nucleation and growth processes, MOCVD processes and emulsion processes. These processes are described in detail in the literature. The sol-gel process was explained above.

The particles may be used in the form of a powder or directly as a dispersion in a dispersant. Examples of commercially available dispersions are the aqueous silica sols from Bayer AG (Levasil®) and colloidal organosols from Nissan Chemicals (IPA-ST, MA-ST, MEK-ST, MIBK-ST). For example, pyrogenic silicas from Degussa (Aerosil products) are available as powders.

Nanoscale particles have a mean particle diameter (volume average, measurement: if possible by X-ray diffraction, although otherwise by dynamic laser light scattering (using an ultrafine particle analyzer (UPA)) of less than 1 μm, as a rule less than 500 nm. The nanoscale solid particles preferably have a mean particle diameter of not more than 300 nm, preferably not more than 200 nm and in particular not more than 50 nm and more than 1 nm and preferably more than 2 nm, e.g. 1 to 20 nm. This material may be used in the form of a powder but is preferably used in the form of a sol or of a suspension.

The nanoparticles may also be surface-modified. The surface modification of nanoscale particles is a known process, as was described by the applicant, for example in WO 93/21127 (DE 4212633) or WO 96/31572. The preparation of the surface-modified particles can in principle be carried out in two different ways, namely firstly by surface modification of already prepared nanoscale particles and secondly by the preparation of these particles with the use of surface modifiers.

Suitable surface modifiers are compounds which firstly have one or more groups which can react or interact with reactive groups (such as, for example OH groups) present on the surface of the nanoparticles. The surface modifiers can, for example, form covalent, coordinate (complex formation) and ionic (salt-like) bonds to the surface of the nanoparticles, while dipole-dipole interactions, hydrogen bridge bonds and van der Waals interactions may be mentioned by way of example among the pure interactions. The formation of covalent bonds is preferred.

Inorganic and organic acids, bases, chelate formers, complexing agents, such as β-diketones, proteins, which may have complex-forming structures, amino acids or silanes, are suitable for surface modification of the nanoparticles. Specific examples of surface modifiers are saturated or unsaturated mono- and polycarboxylic acids, the corresponding acid anhydrides, acid chlorides, esters and acid amides, amino acids, proteins, imines, nitriles, isonitriles, epoxy compounds, mono- and polyamines, β-dicarbonyl compounds, such as β-diketones, oximes, alcohols, alkyl halides, metal compounds which have a functional group which can react with the surface groups of the particles, e.g. silanes having hydrolyzable groups with at least one nonhydrolyzable group, which were described above. Further specific compounds for surface modifiers are mentioned, for example, in the abovementioned WO 93/21127 and WO 96/31572.

The nanoparticles may also be doped with at least one other metal or semimetal. The use of nanoparticles in the binder is a preferred embodiment, the polycondensate described above preferably being prepared in the presence of the nanoparticles, with the result that stronger bonding between binder and polycondensates is achieved. As a result of the nanoparticles, the layers become harder and more scratch-resistant. The nanoparticles can also be added separately to the coating composition. The use of the nanoparticles as the sole binder is, as stated, possible.

Suitable solvents which may be used for the coating composition are both water and organic solvents or mixtures. These are the customary solvents used in the coating sector. Examples of suitable organic solvents are alcohols, preferably lower aliphatic alcohols (C₁-C₈-alcohols), such as methanol, ethanol, 1-propanol, isopropanol, and 1-butanol, ketones, preferably lower dialkyl ketones, such as acetone and methyl isobutyl ketone, ethers, preferably lower dialkyl ethers, such as diethyl ether, or diol monoethers, amides, such as dimethylformamide, tetrahydrofuran, dioxane, sulfoxides, sulfones or butyl glycol and mixtures thereof. Alcohols are preferably used. It is also possible to use high-boiling solvents. In the sol-gel process, the solvent may, if appropriate, be an alcohol formed by hydrolysis from the alcoholate compounds.

The components of the coating composition for the layer containing the oxidation catalyst can be combined in any desired sequence. For example, the oxidation catalyst in the form of a powder, sol or suspension can be added to the binder sol prepared by the sol-gel process. In addition to said components, if appropriate, further additives known to the person skilled in the art in the coating sector may be added if required.

The composition is preferably a dispersion which comprises the oxidation catalyst particles and a binder sol.

For the coating of the substrate with the coating composition, it is possible to use the customary coating methods, for example immersion, roll-coating, coating with a knife coater, flooding, drawing, spraying, spin-coating or brushing on. An expedient application method is application by means of an offset roller. The coating composition applied is, if appropriate, dried and cured or densified.

Particularly in the case of crosslinkable binders, thermal or photochemical curing of the layer is suitable. In the case of photochemical curing, exposure to UV light is expedient. Without crosslinkable groups, the hydrophilic layer is densified or baked by heat treatment. The temperature and duration for curing or densification or baking do of course depend on the materials used. In general, temperatures of from 90 to 600° C. are expedient for densification.

The binders, if used, serve for improving the adhesion, the ratios and the conditions being chosen in a conventional and known manner, and the hydrophilic oxidation catalysts are present on the surface of the finished layer, i.e. at least a part of the oxidation catalysts is not completely surrounded by binder. If an organically modified inorganic polycondensate and/or corresponding nanoscale particles is/are used as the binder, the organic components of the binder may be partly or completely decomposed in the course of the coating procedure (for example during baking) and/or during the subsequent use in the process according to the invention, so that the binder component remaining behind might have only inorganic constituents.

The layer obtained may have a certain porosity since as a rule an improvement in the catalytic activity is associated therewith. However, depending on the wavelength of the exposure, attention should be paid to scattering effects. The coating is therefore expediently a porous layer. A suitable porosity of the layer can be specified, for example by means of a specific surface area of the layer, determined by the BET method using nitrogen, from 20 m²/g to 250 m²/g, preferably from 30 m²/g to 150 m²/g and in particular from 40 m²/g to 80 m²/g.

The layer containing the hydrophilic oxidation catalyst expediently has a dry layer thickness of from 1 to 100 μm, preferably from 2 to 20 μm and in particular from 3 to 10 μm. In contrast, the hydrophobic layer applied thereon is preferably extremely thin. In this context, it may also be designated as a film. The hydrophobic layer preferably has a layer thickness of not more than 100 nm, for example in the range from 50 to 100 nm. Even more preferably, the hydrophobic layer is a very thin layer or even a molecular film, i.e. at least one “stratum” or a few “strata” of the substances forming the hydrophobic layer on the surface of the hydrophilic layer, e.g. mono-, di- or trimolecular layers. The imparting of water repellency is therefore not critical with regard to volume.

The hydrophobic layer is produced in particular by imparting water repellency to the layer containing the hydrophilic oxidation catalyst. Preferably, a water repellent is applied in the customary manner for this purpose. All conventional substances imparting water repellency and known in industry can be used for the water repellent. These may be, for example, hydrocarbons, organic compounds having long alkyl chains or salts thereof, organic polymers or mixtures thereof. The water repellent should as far as possible contain no inorganic radicals. Said water repellents are therefore preferably purely organic substances. The substance imparting water repellency can be used in pure form or preferably in a solvent for the application. One or more substances imparting water repellency can be used. The hydrophobic layer is therefore in particular free of inorganic compounds or radicals in order to ensure complete oxidizability and removability.

Examples of substances imparting water repellency for the hydrophobic layer in the water repellent are paraffins, waxes, fats and oils, relatively long-chain hydrocarbons, fatty acids, oleic acids and soaps. Examples of waxes are natural waxes, such as candelilla wax and carnauba wax, synthetically modified waxes, such as montan ester waxes, or synthetic waxes, such as polyalkylene waxes. Examples of a fatty acid are oleic acid, palmitic acid and in particular stearic acid.

Solvents used may be water and/or organic solvents, such as, for example, hydrocarbons, chlorinated hydrocarbons, ethers, esters, higher alcohols from butanol or the abovementioned solvents. The substance imparting water repellency preferably forms a solution or an emulsion/dispersion, e.g. aqueous emulsions, in the solvent. In addition to the substance imparting water repellency and the solvent, the water repellent may furthermore contain, if appropriate, metallic catalysts, emulsifiers and/or polymers of all types as flexibilizers.

The water repellent is applied in a conventional manner to the hydrophilic layer. Any suitable application method can be used, for example rubbing or the above-mentioned coating methods. As a rule, only drying is effected for evaporating off the solvent. The layer thickness can be controlled, for example, by dilution in the solvent. If appropriate, the heat treatment for stronger bonding to the hydrophilic layer can also be effected. As a rule, however, it is expedient if the substances imparting water repellency do not form a covalent bond with the surface groups of the hydrophilic layer, but such bonds do not have any substantial adverse effects.

The substrate thus obtained is exposed imagewise. The structuring can be effected, for example, by a mask technique, via holographic techniques, e.g. two-wave mixing, near-field optics (e.g. nanolithography) and by laser writing methods. For example, IR light, UV light or light in the visible range can be used for the exposure, the use of laser light being preferred. When a laser light is used, commercially available systems (e.g. laser engraving devices) can be used. The writing speed or the duration of exposure is adapted to the hydrophobic layer thickness and may be in the range from less than 1 s to longer exposure times.

A suitable laser is the CO₂ laser, which operates in the infrared range. More recently, it has been possible to achieve a writing width up to 10 μm with CO₂ lasers. Thus, any desired patterns can be written on such a surface. By exposure to a CO₂ laser, the exposed parts can be heated in a relatively simple manner to the desired temperature. Thus, local heating to about 300° C. can be achieved, by example, with a CO₂ laser, which local heating leads to oxidation and decomposition of the hydrophobic layer with the oxygen of the air in exposed parts.

The use of a UV laser is on the other hand frequently relatively unsuitable if relatively great heating, for example above 300° C., is required, since the energy coupling is very low and heating up of the exposed surface which is sufficient for decomposition is frequently scarcely achievable. If, however, a substance absorbing in the UV range is mixed with the water repellent, the absorption of the UV laser beam increases considerably and the UV radiation is converted into heat by relaxation processes. The UV absorbents are also suitable in the case of exposure to light in the visible range (VIS), but UV light is preferred. With such additives, efficient temperatures increases and therefore also thermally activated oxidation catalyses can be carried out so that, by means of such a measure, UV lasers can also be used in an expedient manner for writing. The advantage of these UV lasers is that the resolution is substantially better than that of CO₂ lasers, so that even finer lines can be written (down to about 1 μm).

Another advantageous exposure method is near-field optics, which can be used, for example, for nanolithography. In the presence of UV absorbents in the hydrophobic layer, it is possible to work in a particularly advantageous manner with near-field optical methods in the range of UV and/or VIS light.

In a preferred embodiment for the use of UV light and/or VIS, the hydrophobic layer therefore contains a UV absorbent, preferably an organic UV absorbent. Examples of UV absorbents are well known to the person skilled in the art and he can choose a suitable one depending on the case. Preferred examples are derivatives of benzophenone, the substituents (e.g. hydroxyl and/or alkoxy groups) preferably being present in the 2- and/or 4-position; substituted benzotriazoles, acrylates phenyl-substituted in the 3-position (cinnamic acid derivatives) and salicylates. Further preferred UV absorbers are natural substances, such as 3-(5-imidazolyl)acrylic acid (urocanic acid) and ergosterol. The concentration of UV absorber in the finished hydrophobic layer is, if used, preferably from 0.1 to 10% by weight, in particular from 2 to 8% by weight and more preferably from 3 to 5% by weight.

The resolution width for the structuring is determined exclusively by the wavelength of the exposure, in particular the width of the laser beam. In principle, it is also possible to achieve very low resolutions by exposure via near-field optical methods in the UV/VIS range (into the nm range). According to the invention, it is therefore possible to form structuring in the micron and/or nanometer range. The structurings achievable by UV exposure in the μm range are sufficient, for example, for the print quality required in the case of books.

As a result of the exposure of the surface, decomposition of the hydrophobic layer in the imagewise exposed regions occurs through the resulting heat in combination with the action of the oxidation catalyst, the hydrophilic oxidation catalyst present underneath being bared in these regions. In this way, the desired structure is formed on the surface.

The structure is preferably a microstructure, i.e. structures having finenesses in the micron range are formed at least in some regions. Without wishing to be tied to one theory, it is assumed that, on the decomposition of the hydrophobic layer, the substances imparting water repellency which are present therein are oxidized and hence decomposed and evaporated off. Residue-free decomposition preferably takes place.

The plates thus obtained and having a structured surface are outstandingly suitable for printing a structure on a receiving medium. Here, a print material that is hydrophobic or hydrophilic is applied to the substrate, the material being deposited only on the hydrophilic/hydrophobic regions of the structured surface of the substrate, owing to the hydrophilic/hydrophobic character. Of course, a hydrophilic material is distributed over the hydrophilic regions of the surface and a hydrophobic material over the hydrophobic regions. The substrate laden with the material is then brought into contact with a receiving medium, pressure expediently being used, and substrate and a receiving medium are then separated from one another with imagewise transfer of the material to the receiving medium.

Apart from the substrate according to the invention, the printing process can be carried out as in the case of a conventional planographic printing process. Examples of planographic printing processes are lithography and offset printing. The structured plate can be used, for example, as a printing plate or printing roller. The print material may be applied, for example, by spraying, immersion, knife coating or spreading or by means of rolls. With the process according to the invention, it is possible to achieve transfer of virtually any desired liquid to pasty components by means of the change from hydrophilicity to hydrophobicity.

The material for printing has a liquid to pasty consistency. For example, aqueous solutions, suspensions or pastes are possible. The customary materials which are known in industry for printing or transfer may be used. These may be, for example, metal-containing pastes, ceramic-containing pastes and semiconductor-containing pastes or corresponding suspensions. If the laden surfaces are pressed onto a receiving medium, the latter interacts with the components present on the laden surface so that an image of the structure can be produced on the corresponding receiving medium. The material transferred to the receiving medium can be dried, cured, densified or further treated in another manner.

The receiving medium may be, for example, one which is suitable for producing microelectronic circuits. It may be, for example, plastic, e.g. a plastic film, metal, paper, glass or a ceramic surface. Of course, the properties of the receiving medium, for example with regard to the hydrophilicity, must be tailored to those of the material for printing.

With the use of the hydrophilic regions, the bared regions can also be overcoated with another hydrophilic layer as a protective layer for avoiding undesired reactions. The immobilization or deposition of the actual material for printing can then be effected on this second hydrophilic layer.

The particular advantage of the subject of the invention consists in the regeneratability of the plates according to the invention, so that already structured plates can also be restructured, i.e. the structuring is reversible and the valuable plate as such is reusable. This is possible at any time, for example after wear, damage or in the case of a desired change of the pattern to be printed.

The regeneration is achieved, for example, in an advantageous manner by cleaning the surface, if appropriate, after use, for example for removing remaining print material, and then removing the hydrophobic regions of the surface structure over the entire surface. The layer thus bared and containing the hydrophilic oxidation catalyst can then be coated again with a hydrophobic layer so that the regeneratable plate can be used for a fresh structuring task.

The removal of the hydrophobic layer over the entire surface is preferably possible by means of two methods. Firstly, the surface can be uniformly exposed in order completely to remove the hydrophobic regions from the surface by thermocatalytic decomposition. The plate can thus be freed from all hydrophobic constituents or any UV absorbents present so that it is completely clean, without any residues, such as pyrolysis products, remaining behind. The regenerated plate can therefore be reused without limitation.

The removal of the hydrophobic layer over the entire surface can also be effected by dissolution using a cleaning agent. A suitable cleaning agent is, for example, any organic solvent in which the water repellent is soluble, e.g. a nonpolar solvent, such as hexane, benzene or toluene, or a surfactant-containing washing agent. Of course, it should be ensured that the cleaning agent does not attack the layer containing the hydrophilic catalyst.

Alternatively, the regeneration can also be effected in a simple manner, if appropriate after cleaning of the surface, by applying a water repellent directly again to the structured surface in order to obtain again a hydrophobic layer over the entire surface without the hydrophobic regions of the old structuring being removed.

After the further imparting of water repellency over the entire surface, the plate regenerated in this manner is then available for restructuring with another image pattern. In this way, unlimited repeatable reuse is possible.

The use of the invention ranges in general from printing processes in the printing industry to a transfer technique in which certain information or structures on the materials applied to the substrate are transferred. A further application is the production of structures, in particular microstructures, such as microreactors, spot plates or reactors for combinatorial applications in which corresponding hydrophilic or hydrophobic regions form. A further application consists in the production of very fine structures in the nanometer or micron range, in which the hydrophilicity or the hydrophobicity is used for holding cells or other biological components in desired arrangements (arrays).

In addition to the pure hydrophilization on the exposed surfaces, it is also possible, in the hydrophilic regions bared by means of the exposure, to carry out reactions with suitable reagents which lead to a chemical change of the surface (for example, introduction of functional groups). Thus, it is possible to produce virtually any desired surface functions, for example by the coupling of functional silanes and the further reaction thereof. Thus, for example, amino groups can be applied to the exposed regions (grafting) and can undergo further customary chemical reactions once, for functionalization purposes (for example via Schiff's base reactions or acid chloride) or which can also serve for the coupling of biological or other components.

Preferred potential applications of these reversibly structurable surfaces are layers having selectable hydrophobic/hydrophilic interactions on the surface from the μm to the nm range, for example for the production of antithrombogenic surfaces for the targeted immobilization of certain cells or other biological components, in particular for the immobilization of enzymes, for implants, for the production of reversible, rewriteable printing plates and printing rollers (digital printing), in particular for offset rollers, the structuring of stone for lithographic printing processes and the production of masters for microoptics and security holograms.

The following example serves for further explaining the present invention.

### EXAMPLE

### 1. Preparation of Binder

For the preparation of the binder, a mixture of 1069.9 g (6.0 mol) of methyltriethoxysilane and 312.5 g (1.5 mol) of tetraethoxysilane is divided into two equal portions. 246.8 g of silica sol (Levasil 300/30, from Bayer) are added to the first portion with stirring. After formation of an emulsion (about 30 s) 5.60 g of 36% strength by weight HCl are added. After a brief stirring (30 to 50 s) the reaction mixture becomes clear with heating. The second portion of the previously prepared silane mixture is rapidly added thereto all at once. After a short time the reaction mixture becomes turbid through a white precipitate (NaCl). Stirring is then effected with cooling in an ice bath for 15 mins. The silane hydrolysis product is allowed to stand for 12 hours at room temperature and is decanted from the solid sediment, and the storable sol is thus obtained. It is adjusted to a degree of hydrolysis of 0.8 before use by activation with hydrochloric acid (8% by mass, addition of 0.108 g of acid per g of sol).

### 2. Preparation of Oxidation Catalyst and Coating Suspension

The catalytically active materials are prepared by impregnating alumina powders with nitrate solutions. 100 g of alumina (Nabalox® NG100) are impregnated with a solution of 22.97 g of manganese nitrate, 27.27 g of copper nitrate and 3.46 g of potassium nitrate in 25 g of water, dried in a drying oven and calcined for one hour at 440° C. 50 g of alumina (Martoxid® MR70) are treated in an analogous manner with a solution of 3.82 g of manganese nitrate, 4.53 g of copper nitrate and 0.57 g of potassium nitrate in 10 g of water.

The coating suspension consists of 10.5 g of NG 100, 4.50 g of MR 70 (weight taken, based on impregnated oxides) and 1.16 g of a black, inorganic pigment (as impregnation on the oxides), 8.25 g of the binder prepared above and 0.89 g of hydrochloric acid for activation. 7.5 g of 2-butoxyethanol are added thereto. For thorough homogeneous mixing, all components (after activation of the binder), except for the NG 100 powder, are thoroughly mixed for 20 min with addition of glass beads in a vibrating mixer and shaken for a further 5 minutes after addition of the NG 100.

### 3. Coating of the Substrate

Stainless steel or enameled metal sheets (Pemco® 52092) were used as substrates. The preliminary cleaning was effected with an isopropanol-KOH solution in an ultrasonic bath (15 min), washing was effected with demineralized water and drying was effected in a drying oven. The suspension prepared above and containing the oxidation catalyst is applied by spraying and dried at from 80 to 100° C. in a drying oven for 20 min. The layer is then cured at 440° C. in a muffle furnace for 1 h.

A wax layer (wax from Aldrich 34,689-6) was applied to the catalytically coated substrate by dip coating (115° C.) at a speed of 4.5 mm/s. A subsequent oven treatment at 140° C. for 20 min was effected for adjusting the wax layer thickness.

### 4. Structuring by Writing Method

The laser system X2-600 from Universal Laser Systems is a CO₂ laser and comprises two different modes of operation, by means of which scanning movements or vector movements are possible. In the scanning movement mode, engraving over an area is possible, in which structuring is effected line by line by forward and backward movement. The vector movement mode permits structuring of contours.

The laser intensity is controlled in that the laser system printer driver assigns a certain intensity from 0 to 100% to each color used in the graphical drawing, 100% corresponding to a laser power of 50 watt. Since the laser is proportionally pulsed, the percentage intensity corresponds to the duration of the laser pulses (with Ø=127 μm). In principle, the intensity setting is based directly on the desired depth of the engraving. Owing to the linear intensity setting, the engraving is twice as deep at an intensity of 100% as at an intensity of 50%.

The wax layer of the coated substrate produced above was exposed to the laser system X2-600 with a power of 5 W and a speed of 50 cm/s. The desired structuring takes place as a result of the heat generated during the laser exposure.

### 5. Evaluation of the Structure Obtained

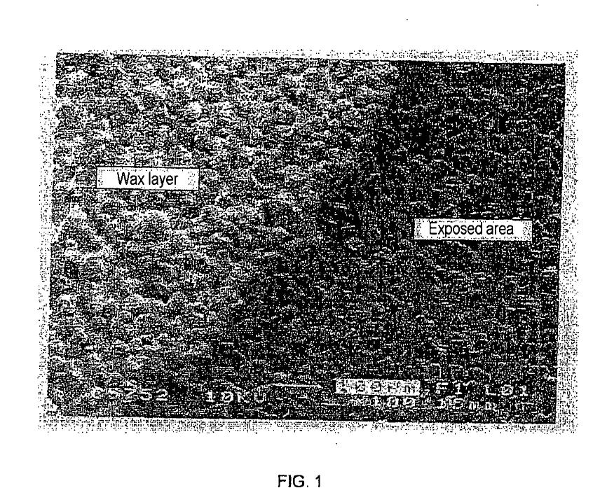

FIG. 1 is a scanning electron micrograph which shows a boundary between regions which were exposed to the CO₂ laser and unexposed regions. It shows that the wax layer which was applied to the catalytically active, porous layer has been destroyed thermocatalytically in the exposed region.

The structure was furthermore evaluated on the basis of the surface energy by contact angle measurement against H₂O. In a preliminary experiment, a contact angle of <10° against H₂O was measured for a layer which contains the oxidation catalyst and to which no hydrophobic layer had been applied. For the structured substrate, a contact angle (H₂O) of 100° (wax layer) was obtained for the unexposed regions whereas the exposed regions had a contact angle (H₂O) of <10°.

Since the exposed regions had the same contact angles as the layer which contains the catalyst and was not treated with a hydrophobic layer, it follows that the wax layer was completely decomposed in the exposed regions by local heating (CO₂ laser exposure).

### 6. Coating without Catalytically Active Species

If a substrate is coated in the same way as in the abovementioned example, except that the aluminas are not impregnated with the catalytically active transition metal oxides, no structuring can be effected by the laser exposure since no thermocatalytic decomposition of the hydrophobic layer is possible.

1.-25. (canceled)

26. A process for making a regeneratable plate having a structured surface comprising hydrophilic and hydrophobic regions, wherein the process comprises imagewise exposing a plate which comprises (a) a substrate, (b) a first layer comprising a hydrophilic oxidation catalyst arranged on the substrate, and (c) a second layer which is hydrophobic and is arranged on the first layer, whereby the first layer is heated in exposed regions to thereby thermocatalytically decompose the second layer and uncover the first layer in the exposed regions.

27. The process of claim 26, wherein the second layer comprises a UV absorbent and a surface thereof is exposed to at least one of UV light and VIS light or by means of near-field optics in at least one of the UV and VIS ranges, whereby the second layer is heated in the exposed regions and is decomposed thermocatalytically.

28. The process of claim 26, wherein the plate is exposed to IR light.

29. The process of claim 26, wherein the plate is exposed to laser light.

30. The process of claim 29, wherein at least one of a UV laser and a CO₂ laser is used.

31. The process of claim 26, wherein at least one of a mask method, a holographic method, a near-field optical method (nanolithography) and a laser writing method is used for the imagewise exposure.

32. The process of claim 26, wherein the first layer has been rendered hydrophobic by application of a water repellent to form the second layer thereon.

33. The process of claim 26, wherein the uncovered first layer is overcoated with another hydrophilic layer as a protective layer or is provided, by reaction with a reagent, with functional groups by means of which any further components can be coupled.

34. The process of claim 26, wherein the first layer comprises a porous layer.

35. The process of claim 26, wherein the hydrophilic oxidation catalyst comprises an IR-absorbing substance.

36. The process of claim 26, wherein the first layer further comprises a binder.

37. The process of claim 36, wherein the binder comprises at least one of a condensate and nanoscale particles.

38. The process of claim 37, wherein the at least one of a condensate and nanoscale particles are formed from a tetraalkoxysilane and at least one silane selected from alkyltrialkoxysilanes, dialkyldialkoxysilanes, aryltrialkoxysilanes and diaryldialkoxysilanes.

39. The process of claim 26, wherein the oxidation catalyst comprises, as the catalytically active component, one or more transition metal oxides.

40. The process of claim 26, wherein the second layer comprises or consists of one or more of paraffin, wax, oil, fat, hydrocarbons, a soap and a fatty acid,

41. The process of claim 26, wherein the second layer is substantially oxidatively destroyed by being heated during the exposure.

42. The process of claim 26, wherein the substrate has been coated with a suspension comprising the oxidation catalyst in a form of particles and, optionally, a binder sol comprising at least one of a condensate and nanoscale particles to form the first layer and the first layer has been covered with a water repellent.

43. A regeneratable plate having a structured surface comprising hydrophilic and hydrophobic regions, wherein the plate comprises (a) a substrate, (b) a first layer comprising a hydrophilic oxidation catalyst arranged on the substrate, and (c) a second layer which is hydrophobic and is imagewise arranged on the first layer, thereby affording the structured surface comprising hydrophobic regions and hydrophilic regions.

44. The plate of claim 43, wherein the second layer contains at least one UV absorbent.

45. The plate of claim 43, wherein the plate is obtainable by a process which comprises imagewise exposing the plate, whereby the first layer is heated in exposed regions to thereby thermocatalytically decompose the second layer and uncover the first layer in the exposed regions.

46. The plate of claim 43, wherein the plate is in a form of a printing plate or a printing roller.

47. A process for regenerating the regeneratable plate of claim 43, wherein the process comprises removing the hydrophobic regions over substantially an entire surface from the structured surface having hydrophilic and hydrophobic regions, and coating the uncovered first layer again with a hydrophobic layer to make the plate available for structuring with a fresh image pattern.

48. The process of claim 47, wherein the hydrophobic regions are removed by at least one of
(a) exposing the entire surface to thereby substantially completely remove the hydrophobic regions by thermocatalytic decomposition, and
b) substantially completely detaching the hydrophobic regions of the structured surface with a cleaning agent.

49. A process for regenerating the regeneratable plate of claim 43, wherein the process comprises coating the structured surface having the hydrophilic and hydrophobic regions as is over an entire surface thereof directly with an additional hydrophobic layer to make the plate available for structuring with a fresh image pattern.

50. A process for printing a material having a liquid to pasty consistency, wherein the process comprises
a) applying a hydrophilic or hydrophobic material to the plate of claim 43, said material being distributed over the hydrophilic regions or over the hydrophobic regions according to a hydrophilic or hydrophobic character thereof,
b) contacting the plate with the hydrophilic or hydrophobic material thereon with a receiving medium to thereby transfer the material imagewise from the plate to the receiving medium.

51. The process of claim 50, wherein the plate is in a form of a printing plate or a printing roller.

52. A printing process or a process for immobilizing biological components, wherein the process comprises using the plate of claim 43.

53. A microelectronic part or an implant or a part having an antithrombogenic surface, wherein the part or implant comprises the plate of claim 43.
